(19) United States
(12) Patent Application Publication
(10) Pub. No.: US 2014/0106543 A1
(43) Pub. Date: Apr. 17, 2014

(54) LASER PROCESSING METHOD FOR WAFER

(71) Applicant: Disco Corporation, Tokyo (JP)

(72) Inventors: Tomohiro Endo, Tokyo (JP); Wakana Onoe, Tokyo (JP)

(73) Assignee: Disco Corporation, Tokyo (JP)

(21) Appl. No.: 14/055,505

(22) Filed: Oct. 16, 2013

(30) Foreign Application Priority Data
Oct. 16, 2012 (JP) 2012-229135

(51) Int. Cl. H01L 21/78

(52) U.S. Cl. CPC H01L 21/78
USPC 438/462

(57) ABSTRACT

A wafer processing method divides a wafer into a plurality of individual devices along a plurality of crossing division lines formed on the front side of the wafer. The wafer has a substrate, a functional layer formed on the front side of the substrate, and a film formed on the back side of the substrate. The method includes a modified layer forming step of applying a laser beam having a wavelength transmitting through the substrate and the functional layer and reflecting on the film along the division lines from the side of the functional layer. The laser beam is first focused at a virtual point set outside the substrate beyond the film and is reflected on the film to focus the beam inside the substrate, thereby forming a modified layer inside the substrate along each division line.

### BACKGROUND OF THE INVENTION

1. Field of the Invention

The present invention relates to a wafer processing method for dividing a wafer into a plurality of individual devices along a plurality of crossing division lines formed on the front side of the wafer, the wafer being composed of a substrate, a functional layer formed on the front side of the substrate, and a film formed on the back side of the substrate, the individual devices being respectively formed in a plurality of regions partitioned by the division lines.

2. Description of the Related Art

In a semiconductor device fabrication process, a plurality of crossing division lines are formed on the front side of a substantially disk-shaped semiconductor wafer to thereby partition a plurality of regions where a plurality of devices such as ICs and LSIs are respectively formed. The semiconductor wafer is cut along the division lines to thereby divide the regions where the devices are formed from each other, thus obtaining the individual devices. Further, an optical device wafer is provided by forming an optical device layer composed of an n-type nitride semiconductor layer and a p-type nitride semiconductor layer on the front side of a sapphire substrate or a silicon carbide substrate. The optical device layer is partitioned by a plurality of crossing division lines to define a plurality of regions where a plurality of optical devices such as LEDs are respectively formed. The optical device wafer is also cut along the division lines to thereby divide the regions where the optical devices are formed from each other, thus obtaining the individual optical devices.

As a method of dividing such a wafer along the division lines, there has been tried a laser processing method of applying a pulsed laser beam having a transmission wavelength to the wafer along the division lines in the condition where the focal point of the pulsed laser beam is set inside the wafer in a subject area to be divided. More specifically, this wafer dividing method using laser processing method includes the steps of applying a pulsed laser beam having a transmission wavelength to the wafer from one side of the wafer along the division lines in the condition where the focal point of the pulsed laser beam is set inside the wafer to thereby continuously form a modified layer inside the wafer along each division line and next applying an external force to the wafer along each division line where the modified layer is formed to be reduced in strength, thereby dividing the wafer into the individual devices (see Japanese Patent No. 3408805, for example).

In the case of an optical device wafer composed of a sapphire substrate and an optical device layer formed on the front side of the sapphire substrate, there has been proposed a technique of forming a reflective film of gold, aluminum, etc. on the back side of the sapphire substrate in order to reflect light emitted from the optical device layer and thereby improve the luminance of each optical device. Further, there has also been put to practical use a wafer having power devices whose back side is covered with a metal film as electrodes.

However, in the case that such a reflective film or metal film is formed on the back side of a wafer, there is a problem such that the reflective film or metal film may hinder the laser beam applied from the back side of the wafer. Further, in the case that the laser beam is applied from the front side of the wafer along each division line in the condition where the focal point of the laser beam is set inside the wafer, there is another problem such that the laser beam may damage a functional layer forming various devices such as ICs, LSIs, and LEDs.

To solve these problems, Japanese Patent Laid-open No. 2011-243875 discloses a technique of applying a laser beam from the back side of a wafer along each division line in the condition where the focal point of the laser beam is set inside the wafer prior to forming the reflective film or metal film as electrodes on the back side of the wafer, thereby forming a modified layer inside the wafer along each division line.

### SUMMARY OF THE INVENTION

In the technique disclosed in Japanese Patent Laid-open No. 2011-243875, however, the modified layer is formed inside the wafer along each division line prior to forming the reflective film or metal film as electrodes on the back side of the wafer. Accordingly, there is a problem such that the wafer may be broken along each division line where the modified layer is formed to be reduced in strength at the time of forming the reflective film or metal film on the back side of the wafer.

It is therefore an object of the present invention to provide a wafer processing method which can form a modified layer inside a wafer along each division line without damage to the functional layer forming the devices even in the case that the reflective film or metal film as electrodes is formed on the back side of the wafer and the laser beam is applied along each division line from the front side of the wafer in the condition where the focal point of the laser beam is set inside the wafer.

In accordance with an aspect of the present invention, there is provided a wafer processing method for dividing a wafer into a plurality of individual devices along a plurality of crossing division lines formed on the front side of the wafer, the wafer being composed of a substrate, a functional layer formed on the front side of the substrate, and a film formed on the back side of the substrate, the individual devices being respectively formed in a plurality of regions partitioned by the division lines, the wafer processing method including: a modified layer forming step of applying a laser beam having a wavelength transmitting through the substrate and the functional layer and reflecting on the film along the division lines from the side of the functional layer in the condition where the focal point of the laser beam is set inside the substrate, thereby forming a modified layer inside the substrate along each division line; and a dividing step of applying an external force to the wafer after performing the modified layer forming step, thereby breaking the wafer along each division line where the modified layer is formed, so that the wafer is divided into the individual devices; the focal point of the laser beam being set inside the substrate so that the laser beam is first focused at a virtual point set outside the substrate beyond the film and next reflected on the film, thereby forming a modified layer inside the substrate along each division line.

Preferably, the substrate is composed of a sapphire substrate, the functional layer is composed of a light emitting layer including an n-type semiconductor layer and a p-type semiconductor layer, and the film is composed of a metal film.

As described above, the wafer processing method according to the present invention includes the modified layer forming step of applying a laser beam having a wavelength transmitting through the substrate and the functional layer and reflecting on the film along the division lines from the side of the functional layer in the condition where the focal point of the laser beam is set inside the substrate, thereby forming the modified layer inside the substrate along each division line. In this modified layer forming step, the focal point of the laser beam is set inside the substrate so that the laser beam is first focused at a virtual point set outside the substrate beyond the film and next reflected on the film. Accordingly, the area of a spot formed by the laser beam on the front side of the functional layer according to the present invention is larger than that in a general setting method for the focal point. For example, the power density of the laser beam applied to the front side of the functional layer in the present invention is reduced to 1/10 or less as compared with the general focal point setting method. Accordingly, even in the case that the film is formed on the back side of the substrate constituting the wafer and the laser beam is applied along the division lines from the functional layer side in the condition where the focal point of the laser beam is set inside the substrate, the modified layer can be formed inside the substrate along each division line without damage to the functional layer forming the devices.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a perspective view of an optical device wafer to be processed by the wafer processing method according to the present invention;

FIG. 1B is an enlarged sectional view of an essential part of the optical device wafer shown in FIG. 1A;

FIG. 2 is a perspective view showing a condition where the optical device wafer shown in FIG. 1A is attached to a protective tape supported to an annular frame;

FIG. 3 is a perspective view of an essential part of a laser processing apparatus for performing a modified layer forming step in the wafer processing method according to the present invention;

FIGS. 4A and 4B are sectional side views for illustrating the modified layer forming step;

FIG. 5 is an enlarged side view for illustrating a general setting method for a focal point;

FIG. 6 is an enlarged side view for illustrating a focal point setting method according to the present invention;

FIG. 7 is a perspective view of a dividing apparatus for performing a dividing step in the wafer processing method according to the present invention; and

FIGS. 8A and 8B are sectional side views for illustrating the dividing step.

### DETAILED DESCRIPTION OF THE PREFERRED EMBODIMENT

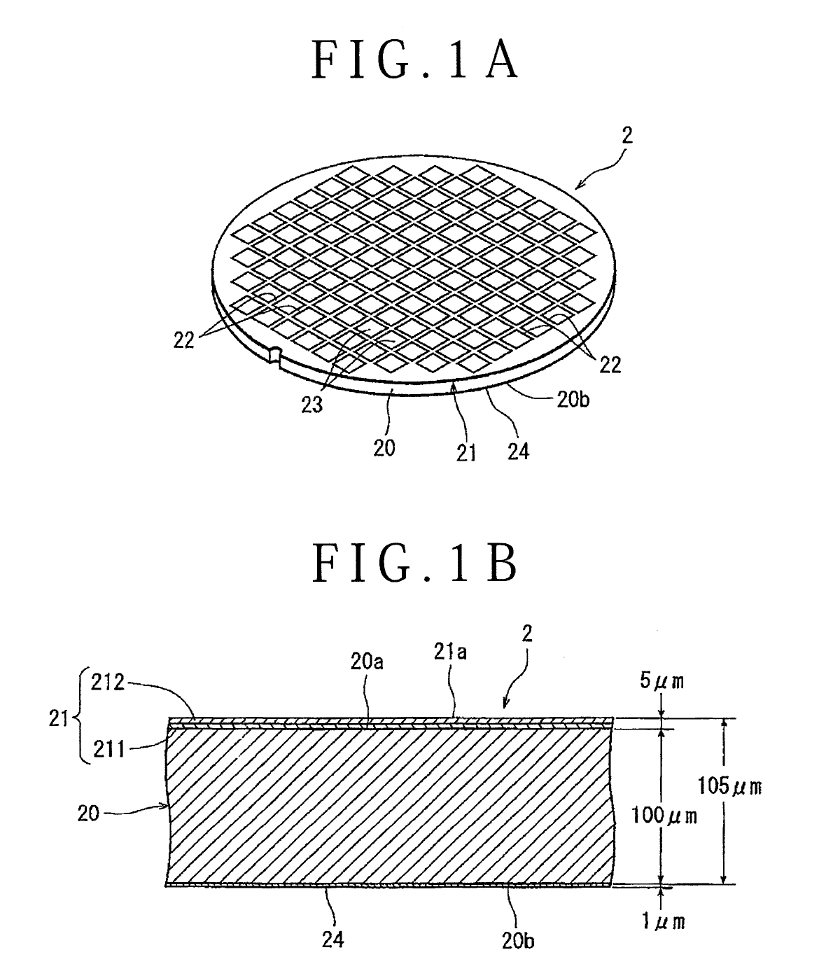

A preferred embodiment of the wafer processing method according to the present invention will now be described in detail with reference to the attached drawings. FIG. 1A is a perspective view of an optical device wafer 2 to be processed by the wafer processing method according to the present invention, and FIG. 1B is an enlarged sectional view of an essential part of the optical device wafer 2 shown in FIG. 1A.

The optical device wafer 2 shown in FIG. 1A includes a substantially disk-shaped sapphire substrate 20 having a front side 20a and a back side 20b and a light emitting layer 21 as a functional layer formed by epitaxial growth on the front side 20a of the sapphire substrate 20. The light emitting layer 21 is composed of an n-type gallium nitride semiconductor layer 211 and a p-type gallium nitride semiconductor layer 212. The material of the light emitting layer 21 is not limited to gallium nitride (GaN), but various other materials such as GaP, GaInP, GaInAs, GaInAsP, InP, InN, InAs, AlN, and AlGaAs may be adopted. Further, a reflective film 24 of metal such as gold and aluminum is formed on the back side 20b of the sapphire substrate 20. For example, the sapphire substrate 20 has a diameter of 100 mm and a thickness of 100 μm, the light emitting layer 21 has a thickness of 5 μm, and the reflective film 24 has a thickness of 1 μm as shown in FIG. 1B. As shown in FIG. 1A, the light emitting layer 21 is partitioned by a plurality of crossing division lines 22 to define a plurality of rectangular regions where a plurality of optical devices 23 such as LEDs are respectively formed. There will now be described a wafer processing method for dividing the optical device wafer 2 along the division lines 22 to obtain the individual optical devices 23.

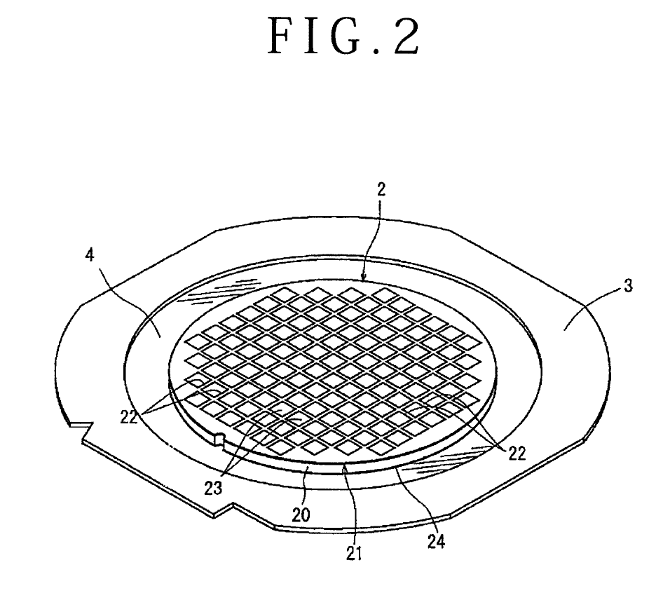

As shown in FIG. 2, the optical device wafer 2 is supported through a protective tape 4 to an annular frame 3 in such a manner that the reflective film 24 formed on the back side 20b of the sapphire substrate 20 is attached to the protective tape 4 (wafer supporting step). The protective tape 4 is preliminarily supported to the annular frame 3. The protective tape 4 is formed from a synthetic resin sheet such as a polyolefin sheet. Accordingly, in the condition where the optical device wafer 2 is supported through the protective tape 4 to the annular frame 3, the light emitting layer 21 formed on the front side 20a of the sapphire substrate 20 so as to constitute the optical devices 23 is oriented upward.

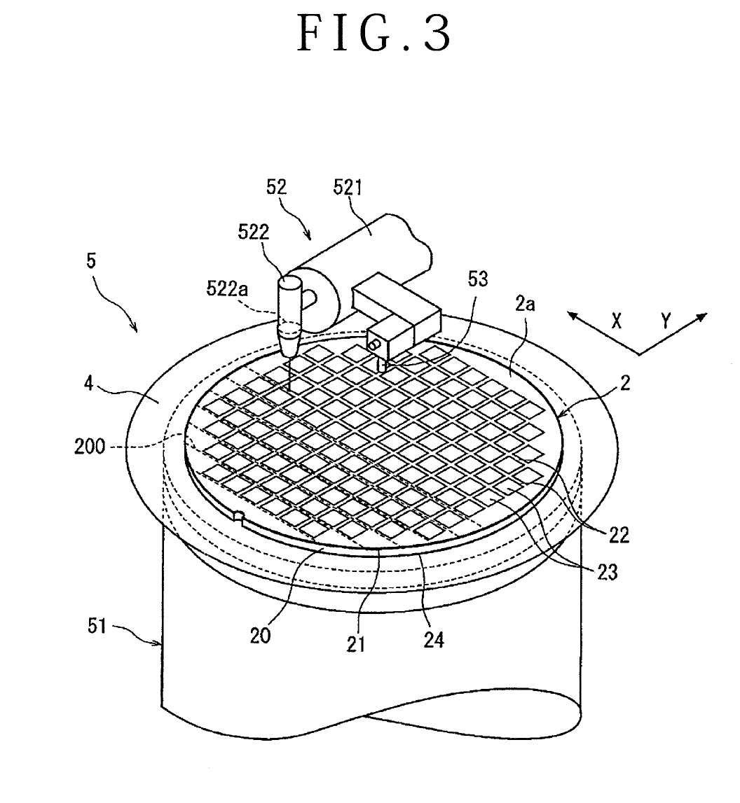

After performing the wafer supporting step mentioned above, a modified layer forming step is performed in such a manner that a laser beam having a wavelength transmitting through the sapphire substrate 20 and the light emitting layer 21 as a functional layer and reflecting on the reflective film 24 is applied along the division lines 22 from the light emitting layer 21 side, i.e., from the front side 20a of the sapphire substrate 20 in the condition where the focal point of the laser beam is set inside the sapphire substrate 20, thereby forming a modified layer inside the sapphire substrate 20 along each division line 22. This modified layer forming step is performed by using a laser processing apparatus 5 shown in FIG. 3. As shown in FIG. 3, the laser processing apparatus 5 includes a chuck table 51 for holding a workpiece, laser beam applying means 52 for applying a pulsed laser beam to the workpiece held on the chuck table 51, and imaging means 53 for imaging the workpiece held on the chuck table 51.

The chuck table 51 has an upper surface as a holding surface for holding the workpiece thereon under suction. The chuck table 51 is movable both in the direction shown by an arrow X in FIG. 3 by feeding means (not shown) and in the direction shown by an arrow Y in FIG. 3 by indexing means (not shown).

The laser beam applying means 52 includes a cylindrical casing 521 extending in a substantially horizontal direction. Although not shown, the casing 521 contains pulsed laser beam oscillating means including a pulsed laser oscillator and repetition frequency setting means. The laser beam applying means 52 further includes focusing means 522 mounted on the front end of the casing 521. The focusing means 522 includes a focusing lens 522a for focusing a pulsed laser beam oscillated by the pulsed laser beam oscillating means. In this preferred embodiment, the numerical aperture (NA) of the focusing lens 522a is set to 0.8.

The imaging means 53 is mounted on a front end portion of the casing 521 constituting the laser beam applying means 52 and includes optical means such as a microscope and a CCD camera. An image signal output from the imaging means 53 is transmitted to control means (not shown).

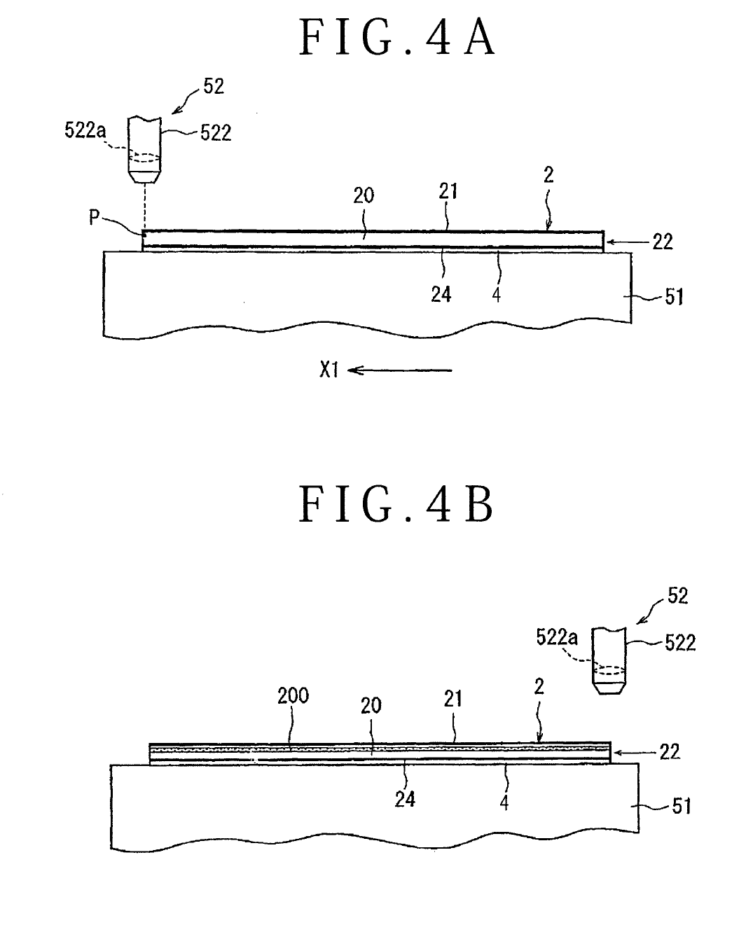

The modified layer forming step using the laser processing apparatus 5 will now be described with reference to FIGS. 3, 4A, and 4B. First, the optical device wafer 2 is placed on the chuck table 51 of the laser processing apparatus 5 in the condition where the protective tape 4 attached to the optical device wafer 2 is in contact with the chuck table 51 as shown in FIG. 3. Thereafter, suction means (not shown) is operated to hold the optical device wafer 2 through the protective tape 4 on the chuck table 51 under suction (wafer holding step). Accordingly, the light emitting layer 21 of the optical device wafer 2 held on the chuck table 51 is oriented upward. Although the annular frame 3 supporting the protective tape 4 is not shown in FIG. 3, the annular frame 3 is actually held by suitable frame holding means provided on the chuck table 51.

After performing the wafer holding step mentioned above, the chuck table 51 thus holding the optical device wafer 2 is moved to a position directly below the imaging means 53 by operating the feeding means (not shown). In the condition where the chuck table 51 is positioned directly below the imaging means 53, an alignment operation is performed by the imaging means 53 and the control means (not shown) to detect a subject area of the optical device wafer 2 to be laser-processed along each division line 22. More specifically, the imaging means 53 and the control means perform image processing such as pattern matching for making the alignment of the division lines 22 extending in a first direction on the light emitting layer 21 of the optical device wafer 2 and the focusing means 522 of the laser beam applying means 52 for applying the laser beam to the wafer 2 along the division lines 22, thus performing the alignment of a laser beam applying position (alignment step). Similarly, the alignment of a laser beam applying position is performed for the other division lines 22 extending in a second direction perpendicular to the first direction on the light emitting layer 21.

After performing the alignment step mentioned above, the chuck table 51 is moved to a laser beam applying area where the focusing means 522 of the laser beam applying means 52 is located as shown in FIG. 4A, thereby positioning one end (left end as viewed in FIG. 4A) of a predetermined one of the division lines 22 extending in the first direction directly below the focusing means 522 of the laser beam applying means 52. Further, the focal point P of the pulsed laser beam to be applied from the focusing means 522 is set at a depth of 50 μm, for example, from the front side (upper surface) of the light emitting layer 21 formed on the front side 20a of the sapphire substrate 20 constituting the optical device wafer 2. A method of setting the focal point P of the pulsed laser beam to be applied from the focusing means 522 will be described later in detail.

Thereafter, a pulsed laser beam having a wavelength transmitting through the sapphire substrate 20 and the light emitting layer 21 and reflecting on the reflective film 24 is applied from the focusing means 522 to the wafer 2, and the chuck table 51 is moved in the direction shown by an arrow X1 in FIG. 4A at a predetermined feed speed. When the other end (right end as viewed in FIG. 4B) of the predetermined division line 22 reaches the position directly below the focusing means 522 of the laser beam applying means 52 as shown in FIG. 4B, the application of the pulsed laser beam is stopped and the movement of the chuck table 51 is also stopped. As a result, a modified layer 200 is formed inside the sapphire substrate 20 of the optical device wafer 2 along the predetermined division line 22 at the depth of 50 μm from the front side (upper surface) of the light emitting layer 21 as shown in FIG. 4B.

For example, the modified layer forming step mentioned above is performed under the following processing conditions.

Light source: LD pumped Q-switched Nd:YVO4 pulsed laser

Wavelength: 1064 nm

Repetition frequency: 100 kHz

Average power: 0.3 W

Numerical aperture (NA) of the focusing lens: 0.8

Focused spot diameter: φ1 μm

Work feed speed: 100 mm/s

After performing the modified layer forming step along all of the division lines 22 extending in the first direction on the light emitting layer 21 of the optical device wafer 2, the chuck table 51 holding the optical device wafer 2 is rotated 90° to similarly perform the modified layer forming step along all of the other division lines 22 extending in the second direction perpendicular to the first direction on the light emitting layer 21 of the optical device wafer 2.

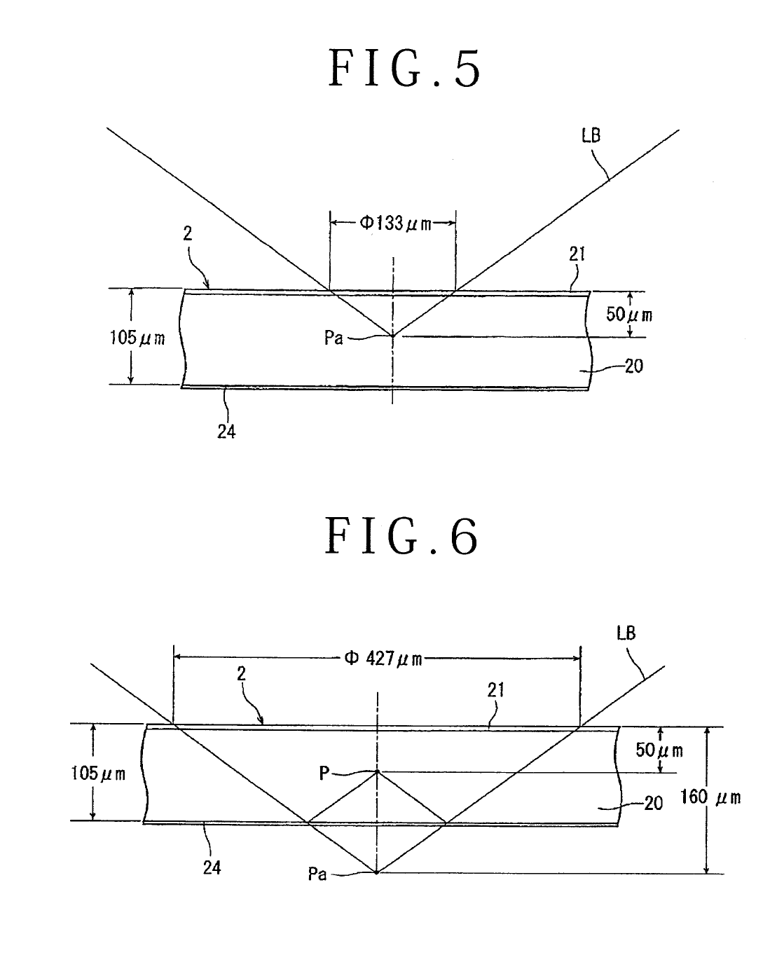

There will now be described a method of setting the focal point P of the pulsed laser beam to be applied from the focusing means 522 at the depth of 50 μm from the front side (upper surface) of the light emitting layer 21 formed on the front side 20a of the sapphire substrate 20 constituting the optical device wafer 2, with reference to FIGS. 5 and 6. FIG. 5 shows a general setting method for a focal point. In this method, the focal point Pa of the pulsed laser beam LB by the focusing lens 522a of the focusing means 522 is set at the depth of 50 μm from the front side (upper surface) of the light emitting layer 21 formed on the front side 20a of the sapphire substrate 20 constituting the optical device wafer 2. In this case, the pulsed laser beam LB to be focused at the focal point Pa has a spot diameter of φ133 μm on the front side (upper surface) of the light emitting layer 21 in the case that the numerical aperture (NA) of the focusing lens 522a is 0.8.

On the other hand, FIG. 6 shows a focal point setting method according to the present invention. In this method, the focal point Pa (virtual point) of the pulsed laser beam LB by the focusing lens 522a of the focusing means 522 is set at the depth of 160 μm below the reflective film 24 from the front side (upper surface) of the light emitting layer 21 (thickness: 5 μm) formed on the front side 20a of the sapphire substrate 20 (thickness: 100 μm) constituting the optical device wafer 2. In this case, the pulsed laser beam LB to be focused at the focal point Pa is reflected on the reflective film 24 formed at the depth of 105 μm from the front side (upper surface) of the light emitting layer 21, and the resultant reflected light is focused at the height of 55 μm from the reflective film 24. Accordingly, the pulsed laser beam LB applied from the focusing means 522 is first reflected on the reflective film 24 formed on the back side 20b of the sapphire substrate 20 constituting the optical device wafer 2 and next focused at the depth (point P) of 50 μm from the front side (upper surface) of the light emitting layer 21 formed on the front side 20a of the sapphire substrate 20. In this case, the pulsed laser beam LB to be focused at the focal point Pa has a spot diameter of φ427 μm on the front side (upper surface) of the light emitting layer 21 in the case that the numerical aperture (NA) of the focusing lens 522a is 0.8.

As described above, in the general focal point setting method shown in FIG. 5, the pulsed laser beam LB is applied to the front side (upper surface) of the light emitting layer 21 with a relatively small area defined by the spot diameter of φ133 μm in the case that the numerical aperture (NA) of the focusing lens 522a is 0.8. To the contrary, in the focal point setting method according to the present invention shown in FIG. 6, the pulsed laser beam LB is applied to the front side (upper surface) of the light emitting layer 21 with a relatively large area defined by the spot diameter of φ427 μm in the case that the numerical aperture (NA) of the focusing lens 522a is 0.8. Accordingly, in the general focal point setting method shown in FIG. 5, the power density of the pulsed laser beam LB applied to the front side (upper surface) of the light emitting layer 21 is 0.0216 J/cm² under the above-mentioned processing conditions. To the contrary, in the focal point setting method according to the present invention shown in FIG. 6, the power density of the pulsed laser beam LB applied to the front side (upper surface) of the light emitting layer 21 is 0.0021 J/cm² under the above-mentioned processing conditions. In this manner, the power density of the pulsed laser beam LB applied to the front side (upper surface) of the light emitting layer 21 in the focal point setting method according to the present invention is reduced to 1/10 or less as compared with the power density in the general focal point setting method. Accordingly, even in the case that the reflective film 24 is formed on the back side 20b of the sapphire substrate 20 constituting the optical device wafer 2 and the laser beam is applied along the division lines 22 from the light emitting layer 21 side in the condition where the focal point of the laser beam is set inside the sapphire substrate 20, the modified layer 200 can be formed inside the sapphire substrate 20 along each division line 22 without damage to the light emitting layer 21 forming the optical devices 23 in the modified layer forming step according to the present invention.

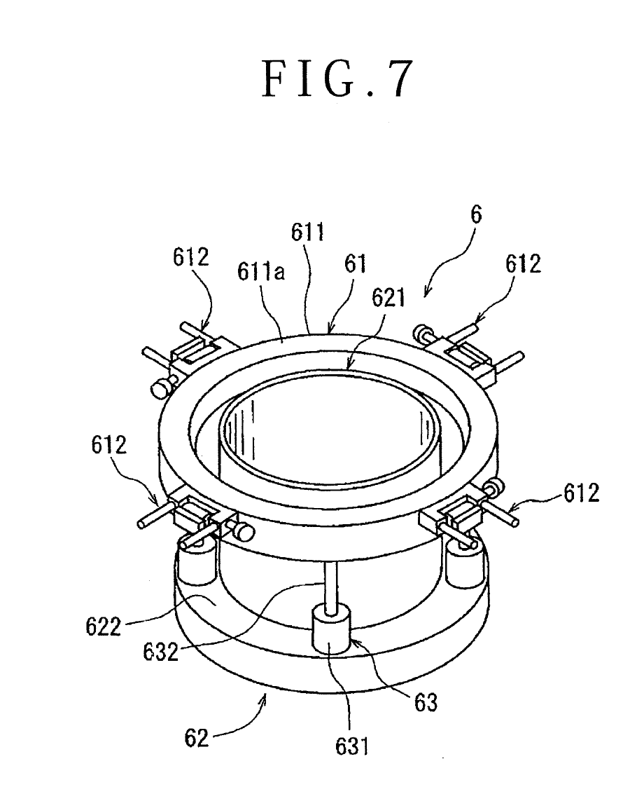

After performing the modified layer forming step as mentioned above, a dividing step is performed in such a manner that an external force is applied to the optical device wafer 2 in the condition where the modified layer 200 is formed inside the sapphire substrate 20 along each division line 22, thereby dividing the optical device wafer 2 along each division line 22. This dividing step is performed by using a dividing apparatus 6 shown in FIG. 7. As shown in FIG. 7, the dividing apparatus 6 includes frame holding means 61 for holding the annular frame 3 and tape expanding means 62 for expanding the protective tape 4 supported to the annular frame 3 held by the frame holding means 61. The frame holding means 61 includes an annular frame holding member 611 and a plurality of clamps 612 as fixing means provided on the outer circumference of the frame holding member 611. The upper surface of the frame holding member 611 functions as a mounting surface 611a for mounting the annular frame 3 thereon. The annular frame 3 mounted on the mounting surface 611a is fixed to the frame holding member 611 by the clamps 612. The frame holding means 61 is supported by the tape expanding means 62 so as to be vertically movable.

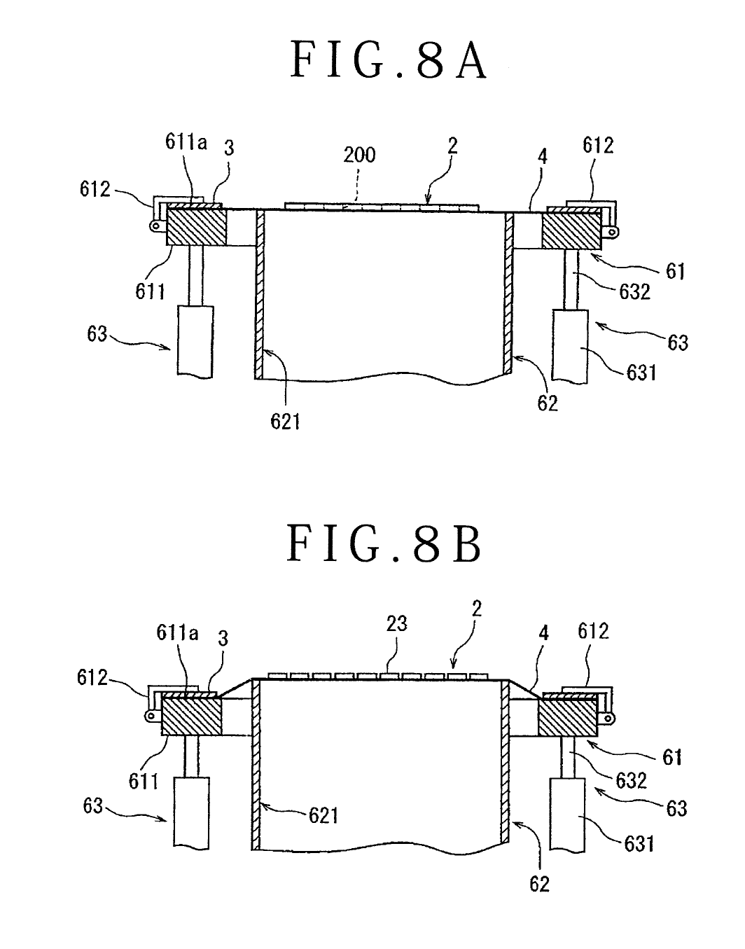

The tape expanding means 62 includes a cylindrical expanding drum 621 provided inside of the annular frame holding member 611. The expanding drum 621 has an outer diameter smaller than the inner diameter of the annular frame 3 and an inner diameter larger than the outer diameter of the optical device wafer 2 attached to the protective tape 4 supported to the annular frame 3. The expanding drum 621 has a supporting flange 622 at the lower end thereof. The tape expanding means 62 further includes supporting means 63 for vertically moving the annular frame holding member 611. The supporting means 63 is composed of a plurality of air cylinders 631 provided on the supporting flange 622. Each air cylinder 631 is provided with a piston rod 632 connected to the lower surface of the annular frame holding member 611. The supporting means 63 composed of the plural air cylinders 631 functions to vertically move the annular frame holding member 611 so as to selectively take a reference position where the mounting surface 611a is substantially equal in height to the upper end of the expanding drum 621 as shown in FIG. 8A and an expansion position where the mounting surface 611a is lower in height than the upper end of the expanding drum 621 by a predetermined amount as shown in FIG. 8B. Accordingly, the supporting means 63 composed of the plural air cylinders 631 functions as moving means for relatively moving the expanding drum 621 and the frame holding member 611 in the vertical direction.

The dividing step using the dividing apparatus 6 will now be described with reference to FIGS. 8A and 8B. As shown in FIG. 8A, the annular frame 3 supporting the optical device wafer 2 through the protective tape 4 (the modified layer 200 being formed inside the sapphire substrate 20 of the wafer 2 along each division line 22) is mounted on the mounting surface 611a of the frame holding member 611 constituting the frame holding means 61 and fixed to the frame holding member 611 by the clamps 612. At this time, the frame holding member 611 is set at the reference position shown in FIG. 8A. Thereafter, the air cylinders 631 as the supporting means 63 constituting the tape expanding means 62 are operated to lower the frame holding member 611 to the expansion position shown in FIG. 8B. Accordingly, the annular frame 3 fixed to the mounting surface 611a of the frame holding member 611 is also lowered, so that the protective tape 4 supported to the annular frame 3 comes into abutment against the upper end of the expanding drum 621 and is therefore expanded substantially in the radial direction of the expanding drum 621 as shown in FIG. 8B (tape expanding step). As a result, a tensile force is radially applied to the optical device wafer 2 attached to the protective tape 4, and the sapphire substrate 20 constituting the optical device wafer 2 is therefore broken along each division line 22 where the strength of the sapphire substrate 20 is lowered because of the presence of the modified layer 200 formed along each division line 22, thereby dividing the optical device wafer 2 into the individual optical devices 23. Thus, the optical device wafer 2 is divided along each division line 22 where the modified layer 200 having a reduced strength is formed as a break start point, thereby obtaining the individual optical devices 23.

Having thus described a specific preferred embodiment of the present invention, the present invention is not limited to the above preferred embodiment, but various modifications may be made within the scope of the present invention. For example, while the present invention is applied to an optical device wafer composed of a sapphire substrate, a light emitting layer formed on the front side of the sapphire substrate, and a reflective film formed on the back side of the sapphire substrate in the above preferred embodiment, it should be understood that similar effects can be obtained also in the case of applying the present invention to a semiconductor wafer composed of a silicon substrate, a plurality of devices such as ICs and LSIs formed on the front side of the silicon substrate, and a metal film formed on the back side of the silicon substrate.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A wafer processing method for dividing a wafer into a plurality of individual devices along a plurality of crossing division lines formed on a front side of said wafer, said wafer being composed of a substrate, a functional layer formed on a front side of said substrate, and a film formed on a back side of said substrate, said individual devices being respectively formed in a plurality of regions partitioned by said division lines, said wafer processing method comprising:
a modified layer forming step of applying a laser beam having a wavelength transmitting through said substrate and said functional layer and reflecting on said film along said division lines from the side of said functional layer in the condition where the focal point of said laser beam is set inside said substrate, thereby forming a modified layer inside said substrate along each division line; and
a dividing step of applying an external force to said wafer after performing said modified layer forming step, thereby breaking said wafer along each division line where said modified layer is formed, so that said wafer is divided into said individual devices;
the focal point of said laser beam being set inside said substrate so that said laser beam is first focused at a virtual point set outside said substrate beyond said film and next reflected on said film, thereby forming a modified layer inside said substrate along each division line.

2. The wafer processing method according to claim 1, wherein said substrate is composed of a sapphire substrate, said functional layer is composed of a light emitting layer including an n-type semiconductor layer and a p-type semiconductor layer, and said film is composed of a metal film.
